(19) United States
(12) Patent Application Publication
(10) Pub. No.: US 2026/0016538 A1
(43) Pub. Date: Jan. 15, 2026

(54) SMART HARDWARE MONITORING AND FAULT DIAGNOSIS USING SENSOR DATA ANALYSIS

(71) Applicant: Tektronix, Inc., Beaverton, OR (US)

(72) Inventors: Krishna N H Sri, Bengaluru (IN); Anurag Koodali Thazathvetil, Bengaluru (IN); Niranjan R. Hegde, Bengaluru (IN); Shubha B, Bengaluru (IN); Kiran Kumar M, Bengaluru (IN); Jonathan L. Tucker, Bengaluru (IN)

(21) Appl. No.: 19/261,643

(22) Filed: Jul. 7, 2025

(30) Foreign Application Priority Data
Jul. 11, 2024 (IN) 202421052998

(51) Int. Cl. G01R 31/34; G06N 20/00

(52) U.S. Cl. CPC G01R 31/34; G06N 20/00

(57) ABSTRACT

A test and measurement instrument includes one or more ports to connect to hardware under test (HUT), a set of sensors connected to the HUT and to the instrument, a display to display one or more signal representations from at least one of the HUT and one or more sensors from the set of sensors, and one or more processors configured to execute code to cause the one or more processors to: acquire data from the set of sensors; form one or more data sets from the data acquired from the set of sensors; apply one or more machine learning models to the one or more data sets; and receive a predictive analysis from the one or more machine learning model about the HUT.

### CROSS-REFERENCE TO RELATED APPLICATIONS

This disclosure claims priority under 35 U.S.C. § 119 to Indian Provisional Patent Application No. 202421052998, titled “SMART MOTOR MONITORING AND FAULT DIAGNOSIS USING SENSOR DATA ANALYSIS,” filed on Jul. 11, 2024, the disclosure of which is incorporated herein by reference in its entirety.

### TECHNICAL FIELD

The disclosure relates to testing of motors and hardware having moving parts, more particularly to applying machine learning to predict future failures of the hardware.

### BACKGROUND

Typically, designers test motors using IMDA (Inverter Motor Drive Analysis) software using voltage and current waveforms during the design and debug phase of the motor design workflow. The software generally measures power quality, DQ0 (direct-quadrature-zero), and harmonics.

One of the common ways to diagnose motors, such as alternating current (AC) motors, brushless DC (BLDC) motors, and one- or three-phase motors, involves using Motor Current Signature Analysis (MCSA) to detect motor faults. One major drawback of this type of motor analysis is that one cannot analyze these motors during in-circuit functioning and these tests occur in controlled environments or lab conditions. Motor designers do not typically run tests on running motors.

Electric motors are exposed to several operational and environmental hazards that cause thermal stress on the windings thus degrading the ability of the motor to insulate the parts form thermal stress and affecting the life expectancy. Hence, motor monitoring has become an important aspect and most effective tactic to locate potential problems. Until recently, preventing motor failure was complex and costly. However, the declining costs of submeters and sensors coupled with advancements in big data technology have made motor monitoring accurate and affordable. All these aforementioned factors are anticipated to drive the growth of the global motor monitoring market over the forecast period.

As referenced at https://www.mordorintelligence.com/industry-reports/motor-monitoring-market, the motor monitoring market size is estimated at USD 2.67 billion in 2024, and is expected to reach USD 4.40 billion by 2029, growing at a compound annual growth rate (CAGR) of 10.46% during the forecast period (2024-2029). The below table summarizes the findings.

| | |
|---|---|
| Study Period | 2019-2029 |
| Market Size (2024) | US 2.67 Billion |
| Market Size (2029) | USD 4.40 Billion |
| Compound Annual Growth Rate (CAGR) | 10.46% |
| Fastest Growing Market | Asia Pacific |
| Largest Market | North America. |

The main players in this market are ABB, National Instrument, Honeywell, Siemens, and General Electric. Those motors consume 70% of the industry's electricity, demonstrating their significance. The market is expanding as consumer preference shifts towards a “shift left” approach and a seamless user experience.

Companies that enable test and measurement solutions for such a growing market will experience growth too.

### BRIEF DESCRIPTION OF ACCOMPANYING DRAWINGS

FIG. 1 shows block diagram of a motor design workflow.

FIG. 2 shows an embodiment of an experimental setup for testing hardware under test (HUT).

FIG. 3 shows an embodiment of sensors mounted on an alternative current motor.

FIG. 4 shows a flowchart of an embodiment of a method of training and selection of a machine learning model.

FIG. 5 shows a flowchart of an embodiment of feature extraction and model.

FIG. 6 shows an example of a vibration signal captured from an AC motor in the time and frequency domains.

FIG. 7 shows embodiments of user interfaces for measurement configuration settings.

FIG. 8 shows an embodiment of a user interface for a machine learning model configuration.

FIG. 9 shows a flowchart of an embodiment of using machine learning to predict hardware failures.

FIGS. 10A-10B show correlation matrices between features and output, and between features.

FIGS. 11A-11B show histograms of correlation and confusion matrices.

FIG. 12 shows an example of a data acquisition trend of vibration plot.

FIG. 13 shows an example of a shaft centerline plot of vibration.

FIG. 14 shows an embodiment of a predictive plot.

### DETAILED DESCRIPTION

The embodiments here address the problem of predictive maintenance and fault diagnosis in an efficient way, which in turn improvise the operation time of Hardware Under Test (HUT). HUTs may comprise various types of hardware, including AC motors, which become integrated with Electric Vehicles (EVs) and industrial applications. The embodiments here apply to all types of motors, including brushless DC motors, 1- and 3-phase motors, but are not limited to motors. Other types of HUTs may involve apparatus that have moving parts whether those parts move under power from a motor or if they move under power of another source. For example, the embodiments here apply to high-speed shafts of wind turbines, which move in response to wind pressure. As used here, the term HUT encompasses these examples and more.

Real time sensors on HUTs allow for collection of large amounts of data. Application of machine learning can use this data to predict future failures accurately. In test and measurement systems, artificial intelligence (AI) and machine learning (ML) have emerged as powerful tools, revolutionizing the data analysis and extraction of insights from that analysis. ML modeling with AI has become an important technology for data processing, providing becomes a valuable tool to monitor live/running HUT systems under dynamic load functions. For ease of discussion, the term machine learning as used here includes aspects of generative AI as well.

The embodiments here involve fault analysis of HUT based on sensors that monitor various reasons for failures such as transient voltage (e.g., surges, voltage and current imbalances, vibration, high operating temperatures, HUT overload, and misalignment). ML models may be used for predictive maintenance of HUT and to predict failures in HUT. While the below discussion focuses on motors, the embodiments apply to other types of systems that operate under other types of power, as mentioned above. Hardware designers will typically be the users in the below process, as the analyses being performed affect the design of the HUT. The term user as used herein applies to the designers who design the hardware, as well as the users that monitor HUT operations for maintenance and repair.

Various industrial and automotive sensors exist that collect analog data to understand and predict the future health of the system. The collection and analysis of the data from these sensors using AI plays a crucial role in HUT monitoring challenges. For example, the analysis can provide insights into predictive maintenance by analyzing vibration data from sensors mounted on HUT. Machine learning can detect anomalies and predict potential faults before the anomalies escalate. This proactive approach minimizes downtime and reduces maintenance costs. ML algorithms identify patterns in vibration signals allowing for diagnosis of issues, like broken rotor bars, bearing defects, and misalignment. Early detection of these issues allows for timely corrective actions. ML leverages historical data to learn HUT behavior, providing insights into optimal operational conditions and fault trends. ML algorithms can run on embedded hardware, such as field-programmable gate arrays, for real-time monitoring, enabling continuous assessment of HUT health. Generally, ML and AI enhance HUT monitoring by predicting faults, optimizing maintenance, and ensuring reliable operation.

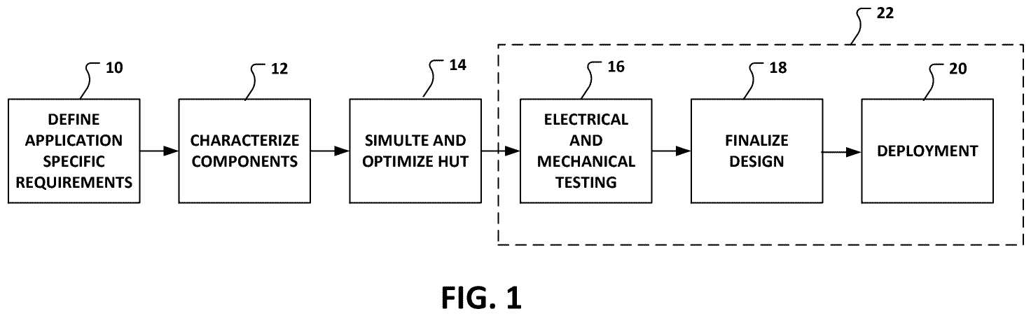

As discussed above, testing HUT while running on an actual test bench is important. FIG. 1 shows an example of a HUT design workflow. The process begins with definition of the application specific requirements for the HUT at 10. The various components used by the HUT are characterized at 12. As discussed above, the users, in this case the designers, simulate and optimize the HUT at 14. The portions of the process inside the box 22 encompass the live testing that allows the designers to finalize their design and deploy and install the HUT. Electrical and mechanical testing occurs at 16, followed by finalizing the design at 18, and deployment at 20. The portions of the process inside the box 22 benefits from the application of ML.

As an example of a HUT, on a running motor with a load, key parameters can be captured from sensor output such as vibration, voltage, current, temperature, acceleration, and strain, among many others. Combined with ML modelling and AI predication for future failures, HUT health can be visualized and analyzed dynamically. This is a new opportunity for the test and measurement industry. The embodiments here apply across several industries to improve HUT operations. The improvements include, without limitation, efficient and fail-safe industrial drives such as conveyor drives and pumps, electric mobility from automotive to drones and electric aircraft, point-of-load converters for data center, safe robots and mobile medical robots with longer battery life, and efficient and predictive PV inverters.

As discussed in more detail further, users can save these parameters as library files for other HUTs with similar specifications, building the in-house knowledge of HUT functions. An AI assistant, meaning a piece of software that employs machine learning, can execute a sequence of operations on the instrument which helps in predicting future failures and improves HUT performance due to mechanical parameter analysis. The AI assistant provides an option for an interface to the AI model that performs the predictive analysis for the HUT.

The embodiments facilitate HUT testing in the box 16 of the workflow of FIG. 1. The ML model adapts based on instrument usage during debugging/testing. Users do not need any large data sets to build the model. The data sets here typically comprise much smaller data sets than typically used, as the models learn dynamically from streaming sensor input as their training process. After integration, users can employ test and measurement instruments, such as oscilloscopes, to test running HUT for mechanical/environmental parameters. In some embodiments, and the test and measurement instruments capture signals from HUT sensors for vibration analysis, which helps identify HUT component harmonics. In some embodiments, the test and measurement instrument may act as a powerful digitizer for sensor data. Faulty waveforms are saved for ML modeling and AI predictions.

Various types of sensors can play crucial roles in identifying potential faults before failure occurs, including vibration sensors. Vibration sensors may take many forms, including MEMS (microelectromechanical system) sensors. These sensors offer reliability and cost-effectiveness, especially excelling at low frequencies. Low frequency monitoring makes the MEMS sensors useful for slow-rotating machinery. Piezoelectric vibration sensors convert mechanical vibrations into electric signals. A wide range of Internet of Things (IoT) industrial sensors exist available from a wide variety of vendors.

Creating a ML model based on sensor data collected from running hardware, such as a HUT, involves several steps. The process aims to analyze the data on a test and measurement instrument such as an oscilloscope. The process involves integrating hardware interfaces, data collection, data preprocessing, model development, visualization, and analysis.

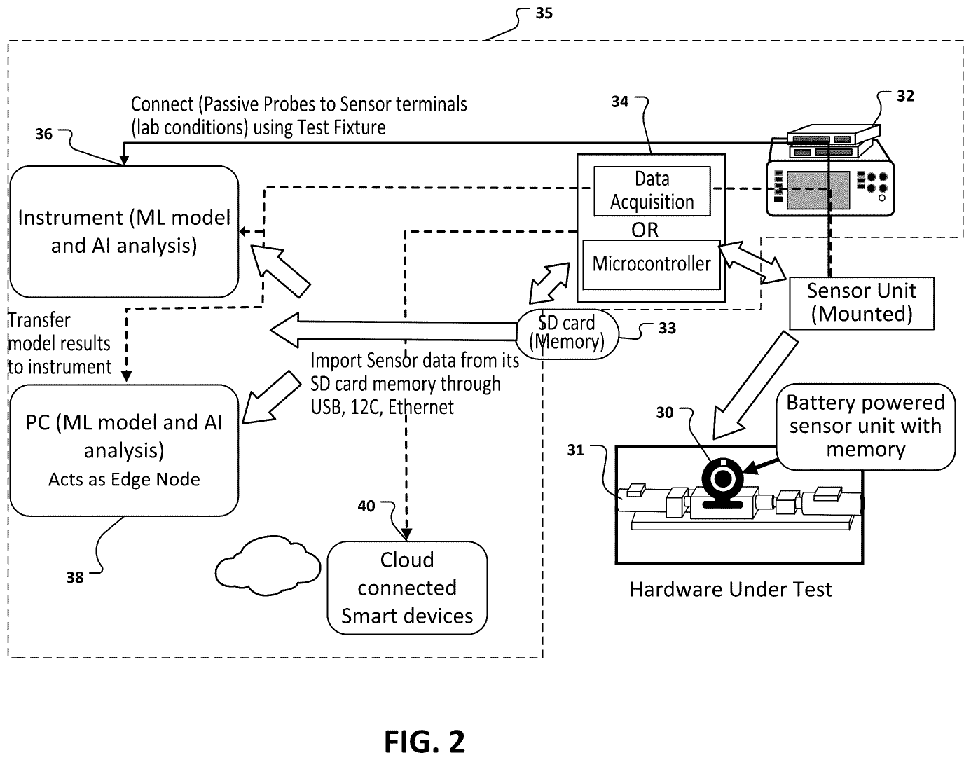

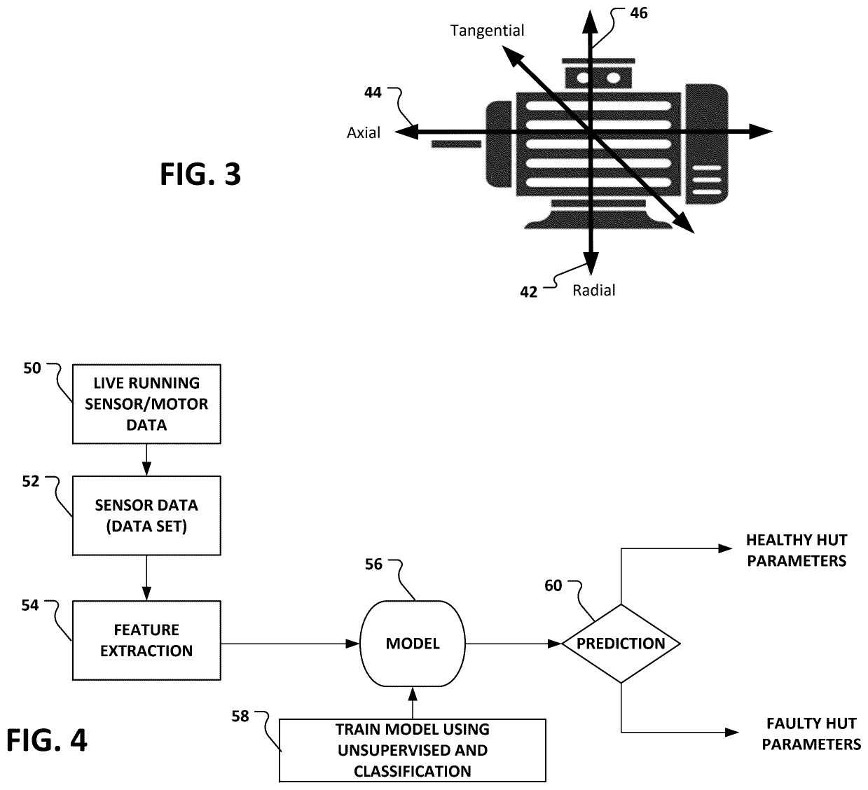

FIG. 2 shows an embodiment of the testing environment. Initially, the sensors like sensor 30 need to be mounted on to the HUT 31. One must fasten the sensors securely and ensure that the sensors are positioned to capture the operational characteristics of the HUT, as shown by sensor 30. The mounted sensor 30 unit provides sensor data that the system 35 can collect in many different ways. For the HUT 31, triaxial sensors, rather than single axis or radial sensors, may provide more information that leads to better fault detection. FIG. 3 shows a configuration of triaxial sensors comprising orientations for an axial sensor 44, a radial sensor 42, and a tangential sensor 46. The sensors, such as sensor 30, undergo conditioning to allow for sensor calibration and detection of sensor failures. The testing setups differ, and the sensor 30 may capture data at the time of sensor failure.

A data logger 34, such as a dedicated data acquisition system or a microcontroller may collect the data. The data logger 34 can then transfer the data to a memory 33 of some kind, such as an SD card, a USB drive, etc. The test and measurement instrument 32 may also collect the data directly. Much of the data may comprise analog data, and many test and measurement instruments, such as oscilloscopes, may include analog-to-digital converters, which converts the data. The test and measurement instrument 32 or the data logger 34 may also collect or transfer the data to a remote store 40, such as a cloud-based memory. The remote store 40 may also receive data sets from the sensor 30 and the results from other components for building of the library previously mentioned.

Test and measurement instrument 32 may also have probes, not shown, connectable to the HUT 31, either directly or using a test fixture. Test and measurement instrument 32 may also include one or more processors to analyze the data and receive and act upon user inputs. The presence of one or more processors and internal memory in test and measurement instrument 32 also allows the ML model and AI analysis 36 to operate on test and measurement instrument 32. Alternatively, or in addition to, test and measurement instrument 32 containing the ML model and AI analysis, a computing device 38, such as a personal computer, may contain the ML model and AI analysis. The different tasks and components discussed below may be distributed between test and measurement instrument 32, the computing device 38, and devices connected through cloud 40.

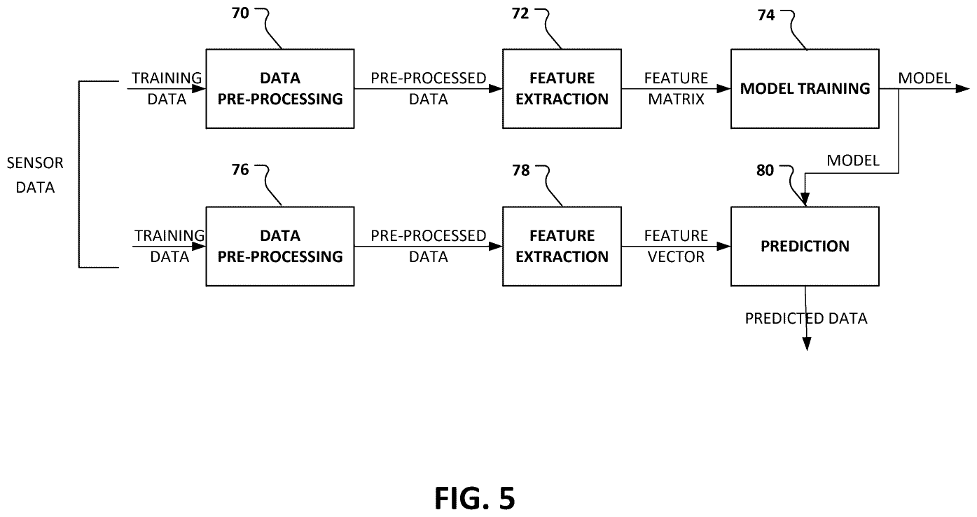

FIG. 4 shows an overall process for gathering and analyzing data collected from the sensors. In FIG. 4, the HUT 31 is running under normal load conditions at 50 and any particular conditions of interest, such as various loads or speeds. The sensors 30 provide data that the system can convert into one or more data sets that represent the operational range of the HUT 31. As mentioned above, test and measurement instrument 32 may act as a real-time monitor, or the data can be logged and stored, either locally or remotely. Using test and measurement instrument 32 as the real-time monitor may have an advantage as the user can view time domain waveforms of the running HUT 31. The probes and/or sensors may connect to the test and measurement instrument 32 through the cloud, antennas, or directly.

After or during collection of the data, the system 35, meaning the combination of the test and measurement instrument 32, and/or the computing device 38, and the remote store 40, consolidates the data into one or more data sets at 52, each of which needs to undergo pre-processing to normalize the data. The one or more data sets undergo standardization to remove biases, improve feature extraction, and improve the training process. For example, to remove any bias from the collected data sets, a normalization process is applied:

$$Normalized Data = \frac{Input data - Mean ( Input data )}{Std Dev ( Input data )} \qquad ( 1 )$$

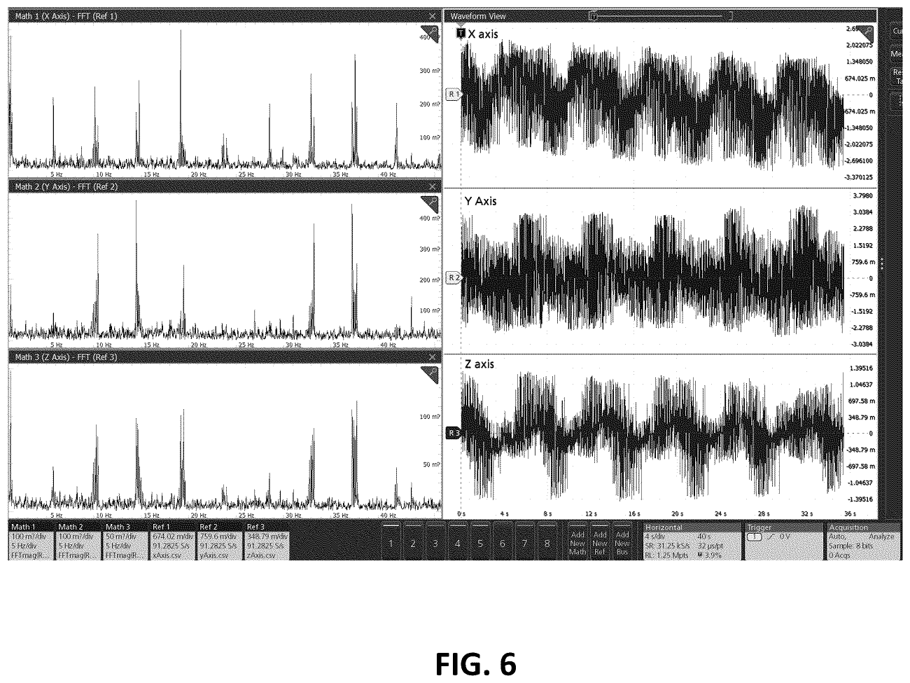

Feature extraction process 54 extracts features from the data that are relevant to the operational characteristics of the HUT 31. This process of feature extraction is discussed in more detail regarding FIG. 5. ML model is then applied to the data set at 56. The model applied to the data set at 45 may be either ML model 36 or ML model 38 from FIG. 2, depending upon at which location the model is running, which may comprise one of many different types of predictive models, including Random Forest, Decision Tree, etc., and may be used for predictive maintenance of the HUT 31, and predict possible failures. The selection of the model may be made by a user through user inputs on the test and measurement instrument 32 or computing device 38, or the user may select “AUTO” on the user interface, shown later. The AUTO option involves choosing the appropriate regression model with the least error for the particular environment in which the HUT 31 operates. Model options include regression models, such as Linear, Multiple, Polynomial, Decision Tree, Neural Networks of which there are several types, or clustering models, as examples without limitation.

The process may apply different error measurements to decide on the most suitable model. Two of these are Mean Square Error (MSE), and Root Mean Square Error (RMSE). The least, or lowest, error is the criteria used to choose the appropriate model. MSE is calculated as:

$$MSE = \frac{1}{n} {\sum }_{i = 1}^{n} {( {Y}_{i} - {\hat{Y}}_{i} )}^{2} ; \qquad ( 2 )$$

RMSE is calculated as:

$$RMSE = \sqrt{\frac{1}{n} {\sum }_{i = 1}^{n} {( {y}_{i} - {\hat{y}}_{i} )}^{2} .} \qquad ( 3 )$$

where n is the number of data points, Yᵢ is the actual i-th measurement value, and Ŷᵢ is its corresponding predicted value in Eq. 2 with the observed values, yᵢ and ŷᵢ in Eq. (3). The AUTO method=min (MSE (regression models, Decision Trees, neural networks, clustering models). The output will be shown as scalar results and trend points.

Returning to FIG. 4, the collected data set is used to train the model at 58. The model undergoes training to recognize patterns or predict outcomes based upon sensor data. This process may occur dynamically as the model receives data streamed from the sensors. The resulting trained model then makes a prediction at 60, which may result in either the HUT being determined to be healthy or having faulty HUT parameters. The faulty HUT parameters may result in maintenance being performed, or the HUT being deemed as failing. The outcome of the model may comprise predictive analyses such as time to failure, predicted maintenance needs, etc. The process evaluates the model's performance using a testing data set. The model parameters may be adjusted as needed to improve accuracy and reduce overfitting.

FIG. 5 shows an embodiment of a feature extraction and model evaluation process. The sensor data is converted into training data sets as mentioned above. The top process performs data pre-processing at 70 such as the normalization/standardization process mentioned above. Features are extracted from the data at 72, resulting in a feature matrix used to train the model at 74. The top process in the figure uses unsupervised learning, where the model essentially trains itself. The bottom process employs classification, in which the data is pre-processed at 76 and undergoes feature extraction at 78. In the classification scheme, however, feature extraction results in a feature vector. The feature vector is then used to predict the performance of the HUT. These two processes may be used in tandem to act as quality control on each other.

In a self-supervised learning (SSL) setup for HUT fault detection, the model learns meaningful representations (embeddings) from raw sensor data without needing labeled examples. These embeddings capture patterns in HUT behavior and serve as rich features for downstream tasks. To predict failure time, a regression model is trained on these embeddings, using some labeled failure data, to estimate the remaining useful life (RUL) of the HUT. This approach enables early fault detection and real-time failure prediction, even in scenarios with limited labeled data. Failure prediction also accounts for the movement/drift of the condition data into failure modes/abnormal modes at runtime.

When modeling the behavior or condition of a running HUT using sensor outputs, extracting the right features from the data such as at 72 or 78 in FIG. 5, 54 in FIG. 4, is crucial for developing an accurate and reliable machine learning model.

A “feature” may comprise almost anything that is extracted from the raw data. It could be the raw data itself, combinations of different sensor data, statistical analysis on several measurements, such as mean, variance, standard deviation, etc., or transformations, such as the Fourier transform to the frequency domain.

The user may pick the features, and then the model is trained using those features. From then on, whenever the process uses that model to make predictions/classifications, the process must extract the same features from new data. As examples, without limitation, features may comprise one or more of time-domain measurements, frequency-domain parameters, harmonic analysis such as by Fast Fourier Transforms (FFT), temperature rise wherein a gradual increase in temperature can indicate friction, misalignment, or electrical issues, vibration patterns in which changes in vibration patterns can indicate imbalance, bearing faults, or misalignment. Vibrational analysis generally comprises one of the most critical features for the designers. Vibration analysis can detect a variety of faults at early stages, including imbalance, bearing failures, and gear faults among many others. These present just some examples among many other possibilities. Combining vibration data with other sensor outputs, such as temperature, current draw, and acoustic emissions, can provide a more comprehensive understanding of the HUT's condition. The integration of these data sources, along with sophisticated machine learning models, can significantly enhance predictive maintenance strategies, reduce unplanned downtime, and extend the lifespan of the HUT.

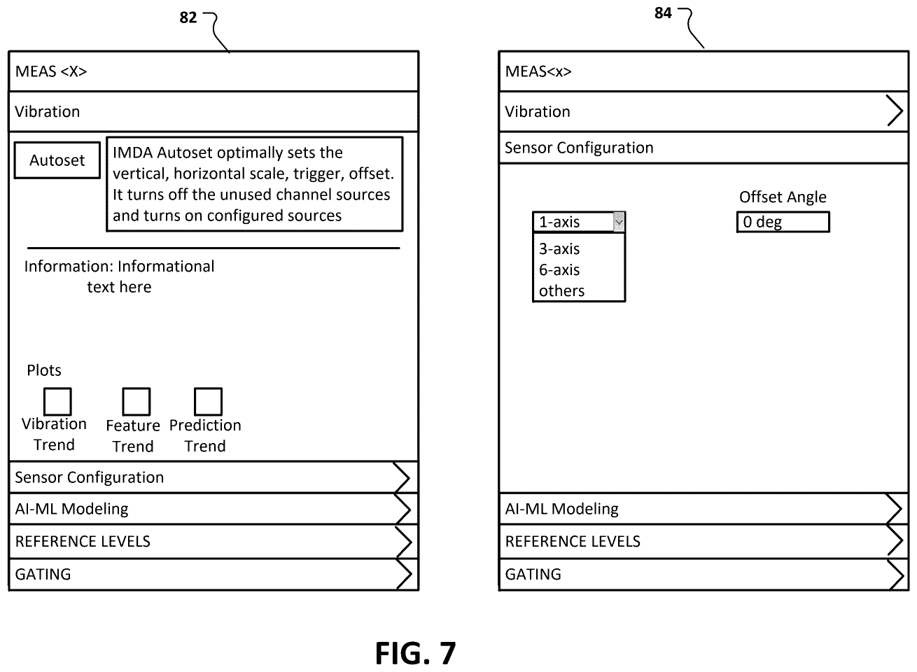

The use of frequency domain parameters allows for clearer understanding of complex vibration waveforms, sometimes difficult to understand in the time domain. The test and measurement instrument can convert the model output into a format that a user can visualize on the test and measurement instrument. This conversion may involve generating a time series prediction or simulating sensor output under hypothetical conditions. The sensor data can be displayed as voltage in Volts/second in the time domain, and its accompanying frequency domain plots. Time domain sensor information can convert to frequency domain sensor information by Dominant peaks=max (ABS(FFT(Sensor_output_data))) as Equation (4). FIG. 6 shows an example of a test and measurement instrument such as an oscilloscope showing the model's output in real time. The user can use the analysis tools on the test and measurement instrument to gain insight into the HUT or HUT operation, and the model's predictive capabilities. The model can be adjusted as needed based upon these observations.

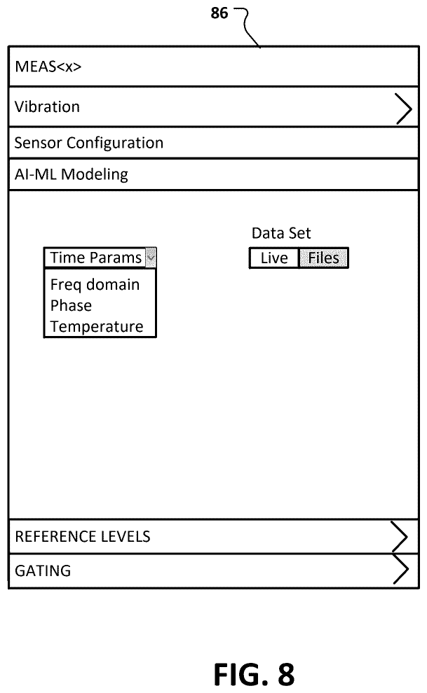

FIG. 7 shows the user interfaces for configuring measurements. The user interface 82 on the left of FIG. 7 shows the options available in one embodiment of the interface. The user selects the type of plots used from the measurements. In this embodiment of the user interface 82 the supported plots may include vibration trend, feature trend, prediction trend, a shaft centerline plot, a correlation/confusion histogram plot, and correlation/confusion tables. The user interface 84 on the right of FIG. 7 shows examples of sensor configurations. In this particular embodiment, the user configures the nature of the axis sensors used in HUT analysis, such as those shown in FIG. 3

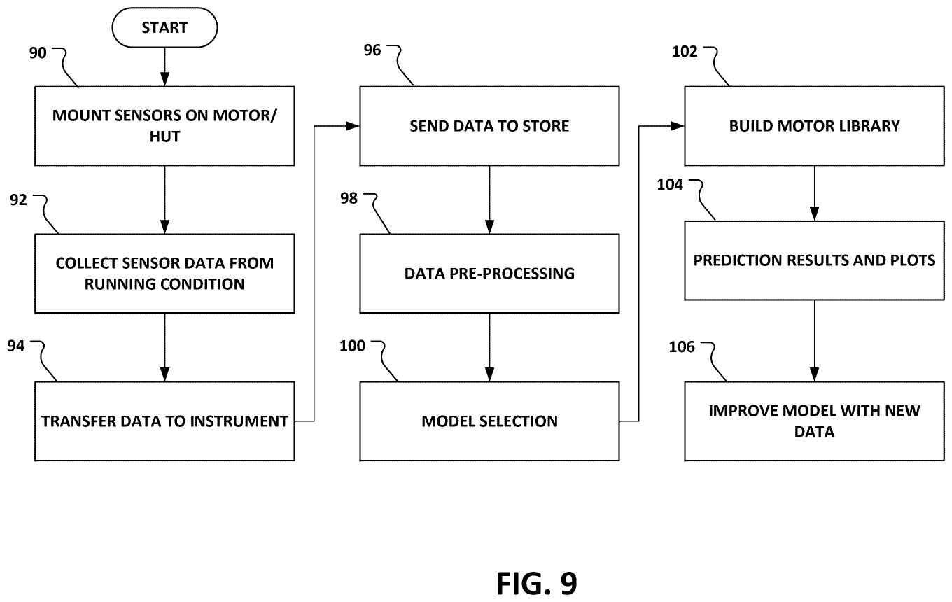

FIG. 8 shows the user interface 86 when the user selects the configuration for the AI-ML modeling. In this example, the user selects the time parameters and whether to use live data, or data from files. Generally, selection of the AI-ML modeling on the test and measurement instrument causes the proposed application to start collecting data on the key features along with metadata including vibration, temperature, etc. The acquired waveforms and data are pre-processed and cleaned, such as resampling, detrending, smoothing, filtering, etc., before extracting the key features. The extracted features are used as a training set for building the model. Once a sufficient training set has been collected, the model trains dynamically in the background. The model undergoes cross validation with another data set to verify accuracy and correctness. If the model accuracy is high enough, the application enables the user to use the model for predicted results in addition to measured results. This process repeats or operates simultaneously for each of the available models.

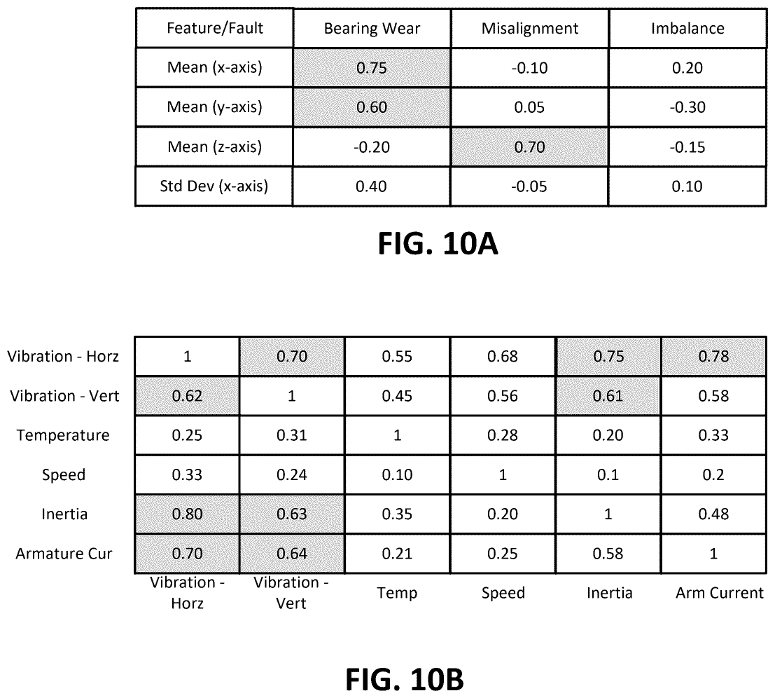

FIG. 9 shows a flowchart of an overall embodiment of a ML process for predictive HUT or HUT behavior. The process begins with the mounting of the sensors to the HUT at 90. The HUT is then started, and data is collected in the running condition at 92. The data is then transferred to the test and measurement instrument at 94, as discussed above, either directly, through a data logger, or from the cloud, the data may also then be sent to a store, such as the cloud, at 96. The data undergoes pre-processing at 98. The model is selected at 100. As mentioned above, the user may select the model, or the system may select the model when the user selects AUTO. The model and the associated data for the particular HUT and the environment may be stored to build the HUT library at 102. The selected model produces the prediction results of either predictive maintenance or indication of healthy or failing HUT at 104. The sensor data used for this cycle is then used to update the model to adjust its operation as needed at 106.

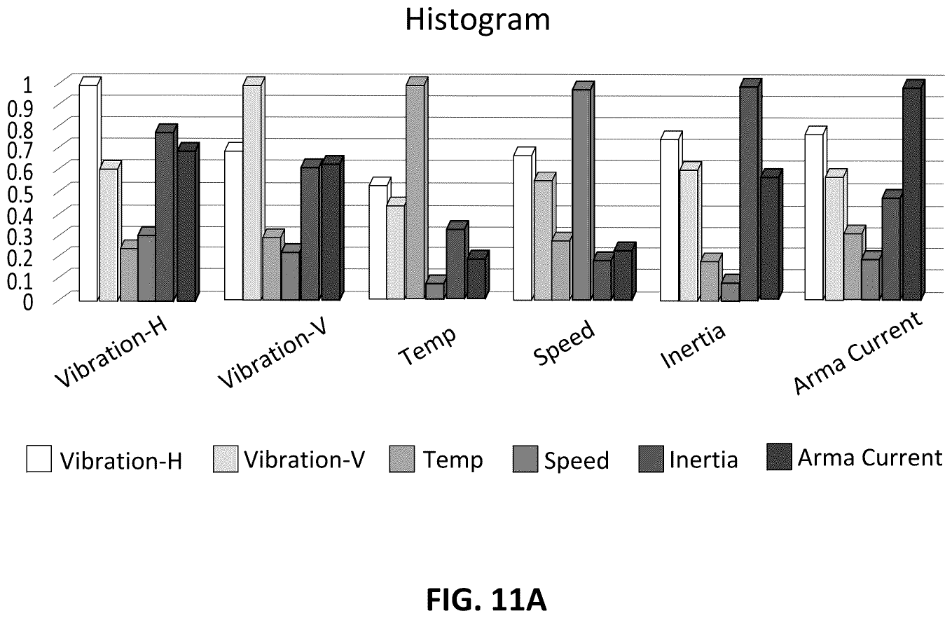

As mentioned above, one analysis of models involves correlation and confusion matrices. A correlation matrix displays the interdependency of extracted features in terms of scalar values. The correlation matrix helps understand the relationship between features and identify potential issues like multicollinearity. FIG. 10A shows a table of mean measurements that indicate relationships between failures and faults and bearing wear, misalignment, and imbalance. FIG. 10B shows that both horizontal and vertical vibration have direct relationships with speed, temperature, and armature current. The shaded boxes in both FIGS. 10A and 10B indicate possible causes of failures. For example, if vibration has a higher correlation, meaning close to 1, with respect to temperature, it means that vibration increases at higher temperatures. In FIG. 10B, horizontal and vertical vibration has direct relationships with inertia, as an example.

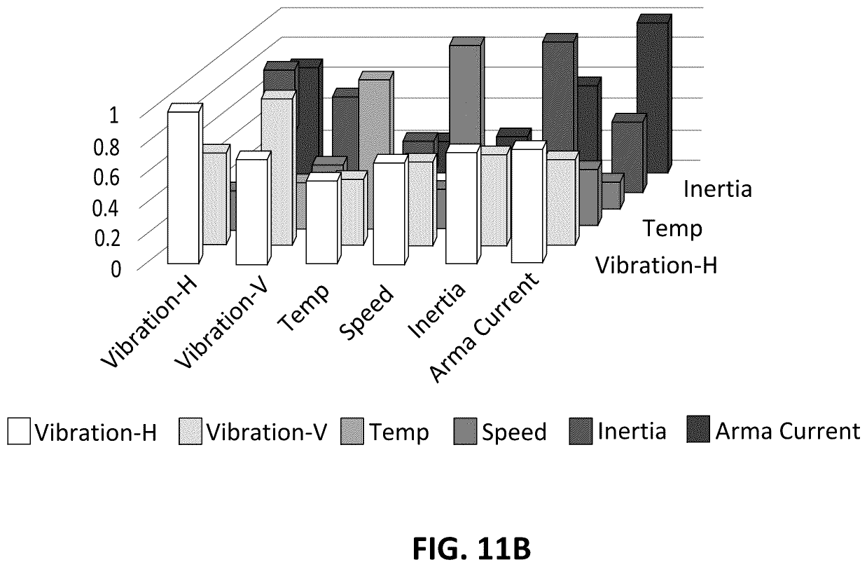

Correlation can also be viewed in bar graphs, which may help in visualizing the interdependence of feature distribution. FIG. 11A shows a histogram of correlation and confusion. FIG. 11B shows an example of a 3D histogram of a confusion matrix. The Y-axis in these diagrams comprise the correlation measure.

Using the confusion histogram of FIG. 11B, one can develop a confusion matrix that generally compares the true negatives, true positives, false negatives and false positives between the predicted results and the actual results, to show how often the model is confused between different classes.

| | Predicted Normal | Predicted Faulty |
|---|---|---|
| True Normal | 90 (True Positive) | 10 (False Positive) |
| True Faulty | 5 (False Negative) | 95 (True Negative) |

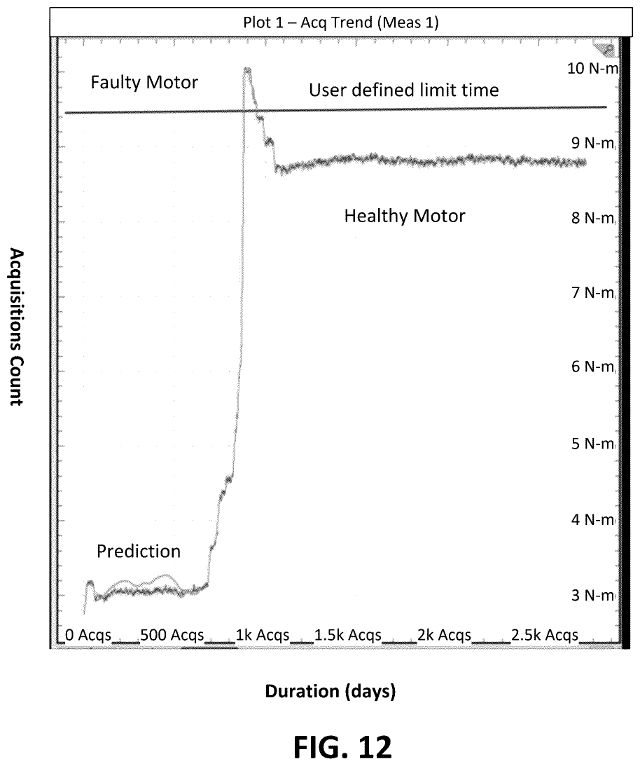

In addition, data acquisition ( ) trend plots visualize how a measured parameter changes over time based upon the order in which data was acquired. FIG. 12 shows an ACQ trend plot for the extracted feature of vibration data. The plot shows a limit line/mask defined by the user. This assists in separating good versus bad HUT behavior.

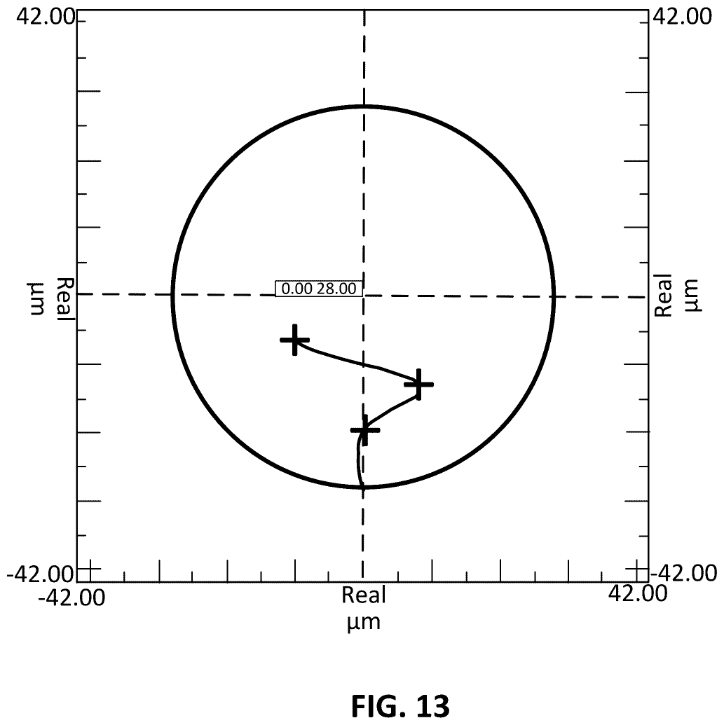

FIG. 13 shows a centerline plot used to analyze the rotor shaft position with respect to bearing. Centerline plots can show important issues including imbalance, bearing stiffness, fluid instability, etc. X and y position sensor data builds the plot over time. The centerline plot is an incremental plot, and the crosshairs indicate the position of the running shaft, as seen from cross section view. This plot helps in knowing the mechanical issues building up in the rotor over time when the shaft position is shifted. X and Y axes indicate the output of the two position sensors. The circle indicates the diameter of the gap in the bearing. The diameter of this circle is the maximum that the rotor shaft can move in horizontal or vertical directions. This diameter is a user input to the plot settings.

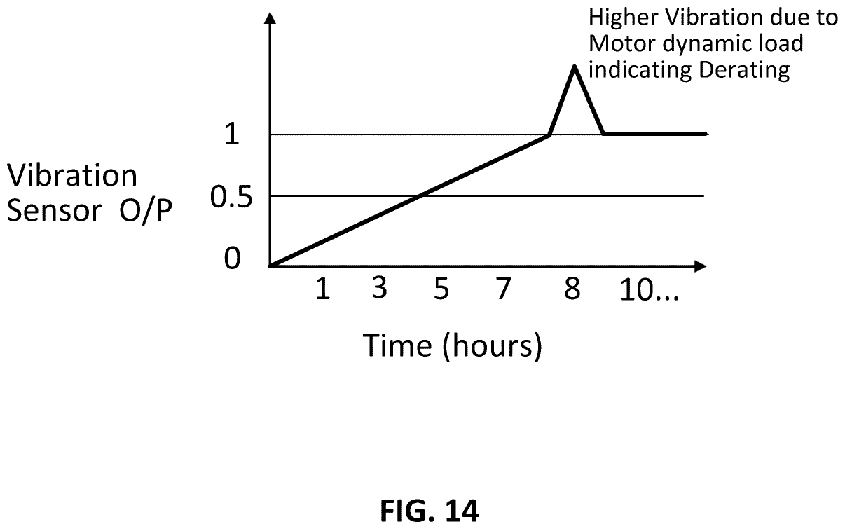

FIG. 14 shows an example of a graphical pass/fail. The vibration value versus time shows that the HUT is damaged after 8 hours of operation. One can define limits for scalar results and can insert a mask for pass/fail. The above plots provide examples of dynamic plots that indicate the model outcomes.

In this manner, sensors attached to the HUT can provide data for ML models to determine predictive behaviors for the HUT, such as pass/fail, healthy or failing, or needing maintenance. A ML model operates to make a predictive analysis of the motor performance. Several ML models may be available, and the test and measurement instrument or computing device upon which they are operating may select the model with the lowest error. The models may be supervised learning models and unsupervised learning models including self supervised learning models.

Aspects of the disclosure may operate on a particularly created hardware, on firmware, digital signal processors, or on a specially programmed general purpose computer including a processor operating according to programmed instructions. The terms controller or processor as used herein are intended to include microprocessors, microcomputers, Application Specific Integrated Circuits (ASICs), and dedicated hardware controllers. One or more aspects of the disclosure may be embodied in computer-usable data and computer-executable instructions, such as in one or more program modules, executed by one or more computers (including monitoring modules), or other devices. Generally, program modules include routines, programs, objects, components, data structures, etc. that perform particular tasks or implement particular abstract data types when executed by a processor in a computer or other device. The computer executable instructions may be stored on a non-transitory computer readable medium such as a hard disk, optical disk, removable storage media, solid state memory, Random Access Memory (RAM), etc. As will be appreciated by one of skill in the art, the functionality of the program modules may be combined or distributed as desired in various aspects. In addition, the functionality may be embodied in whole or in part in firmware or hardware equivalents such as integrated circuits, FPGA, and the like. Particular data structures may be used to more effectively implement one or more aspects of the disclosure, and such data structures are contemplated within the scope of computer executable instructions and computer-usable data described herein.

The disclosed aspects may be implemented, in some cases, in hardware, firmware, software, or any combination thereof. The disclosed aspects may also be implemented as instructions carried by or stored on one or more or non-transitory computer-readable media, which may be read and executed by one or more processors. Such instructions may be referred to as a computer program product. Computer-readable media, as discussed herein, means any media that can be accessed by a computing device. By way of example, and not limitation, computer-readable media may comprise computer storage media and communication media.

Computer storage media means any medium that can be used to store computer-readable information. By way of example, and not limitation, computer storage media may include RAM, ROM, Electrically Erasable Programmable Read-Only Memory (EEPROM), flash memory or other memory technology, Compact Disc Read Only Memory (CD-ROM), Digital Video Disc (DVD), or other optical disk storage, magnetic cassettes, magnetic tape, magnetic disk storage or other magnetic storage devices, and any other volatile or nonvolatile, removable or non-removable media implemented in any technology. Computer storage media excludes signals per se and transitory forms of signal transmission.

Communication media means any media that can be used for the communication of computer-readable information. By way of example, and not limitation, communication media may include coaxial cables, fiber-optic cables, air, or any other media suitable for the communication of electrical, optical, Radio Frequency (RF), infrared, acoustic or other types of signals.

### Examples [Filled Out after Claims are Finalized]

Illustrative examples of the disclosed technologies are provided below. An embodiment of the technologies may include one or more, and any combination of, the examples described below.

Example 1 is a test and measurement instrument, comprising: one or more ports to connect to hardware under test (HUT); a set of sensors connected to the HUT and to the instrument; a display to display one or more signal representations from at least one of the HUT and one or more sensors from the set of sensors; and one or more processors configured to execute code to cause the one or more processors to: acquire data from the set of sensors; form one or more data sets from the data acquired from the set of sensors; apply one or more machine learning models to the one or more data sets; and receive a predictive analysis from the one or more machine learning model about the HUT.

Example 2 the test and measurement instrument of Example 1, wherein the set of sensors connected to the instrument connect to the instrument through a sensor data collector comprised of one of a microcontroller or a data logger.

Example 3 is the test and measurement instrument of either of Examples 1 or 2, wherein the code that causes the one or more processors to acquire data comprises code that causes the one or more processors to acquire data from one of either the sensors or from a remote store.

Example 4 is the test and measurement instrument of any of Examples 1 through 3, wherein the code that causes the one or more processors to form one or more data sets comprises code that causes the one or more processors to normalize the data, and form one or more training data sets, one or more testing data sets, and one or more prediction data sets.

Example 5 is the test and measurement instrument of any of Examples 1 through 4, wherein the code that causes the one or more processors to apply one or more machine learning models to the one or more data sets comprises code that causes the one or more processors to: receive, through a user interface, an input identifying a selected model to apply to the one or more data sets; and apply the selected model to the one or more data sets.

Example 6 is the test and measurement instrument of Example 5, wherein the input identifying a selected model comprises an automatic selection, and the code that causes the one or more processors to apply machine learning comprises code that causes the one or more processors to apply a machine learning model with a lowest error rate.

Example 7 is the test and measurement instrument of any of Examples 1 through 6, wherein the one or more processors are further configured to execute code that causes the one or more processors to train one or more of the machine learning models dynamically at runtime using data streamed from the sensors.

Example 8 is the test and measurement instrument of any of Examples 1 through 7, wherein the code that causes the one or more processors to apply machine learning to the data sets comprises code that causes the one or more processors to: apply the one or more machine learning models to one or more training data sets to train the one or more machine learning models; use one or more testing data sets to test the one or more machine learning models; and adjust parameters for the multiple models to increase accuracy of the multiple models.

Example 9 is the test and measurement instrument of Example 8, wherein the code that causes the one or more processors to apply the one or more machine learning models to one or more data sets to train the one or more machine learning models comprises code that causes the one or more processors to perform feature extraction on the one or more data sets of sensor data.

Example 10 is the test and measurement system of any of Examples 1 through 9, wherein the one or more processors are further configured to execute code to cause the one or more processors to produce plots indicating outcomes from the one or more machine learning models.

Example 11 is a method, comprising: receiving data from a set of sensors connected to hardware under test (HUT); forming one or more data sets from the data acquired from the set of sensors; applying one or more machine learning models to the one or more data sets; and receiving one or more predictions from the one or more machine learning model about likelihood of failure of the HUT.

Example 12 is the method of Example 11, wherein receiving data comprises receiving the data from one of either the sensors or from a remote store.

Example 13 is the method of either of Examples 11 or 12, wherein forming one or more data sets comprises normalizing the data, and forming one or more training data sets, one or more testing data sets, and one or more prediction data sets.

Example 14 is the method of any of Examples 11 through 13, applying one or more machine learning models to the one or more data sets comprises: receiving, through a user interface, an input identifying a selected model to apply to the one or more data sets; and applying the selected model to the one or more data sets.

Example 15 is the method of any of Examples 11 through 13, wherein the input identifying a selected model comprises an automatic selection, and applying the machine learning model comprises applying the machine learning model with a lowest error rate.

Example 16 is the method of any of Examples 11 through 13, further comprising training one or more of the machine learning models dynamically at runtime using data streamed from the sensors.

Example 17 is the method of any of Examples 11 through 13, wherein applying the machine learning to the data sets comprises: applying the one or more machine learning models to one or more training data sets to train the one or more machine learning models; using one or more testing data sets to test the one or more machine learning models; and adjusting parameters for the multiple models to increase accuracy of the multiple models.

Example 18 is the method of Example 17, wherein applying the one or more machine learning models to one or more data sets to train the one or more machine learning models comprises performing feature extraction on the one or more data sets of sensor data.

Example 19 is the method of any of Examples 11 through 18, receiving one or more predictions from the one or more machine learning models comprises converting the predictions from the one or more machine learning models to a format that can be displayed on the display.

Example 20 is the method of any of Examples 11 through 19, further comprising producing plots indicating outcomes from the one or more machine learning models.

All features disclosed in the specification, including the claims, abstract, and drawings, and all the steps in any method or process disclosed, may be combined in any combination, except combinations where at least some of such features and/or steps are mutually exclusive. Each feature disclosed in the specification, including the claims, abstract, and drawings, can be replaced by alternative features serving the same, equivalent, or similar purpose, unless expressly stated otherwise.

Additionally, this written description makes reference to particular features. It is to be understood that the disclosure in this specification includes all possible combinations of those particular features. Where a particular feature is disclosed in the context of a particular aspect or example, that feature can also be used, to the extent possible, in the context of other aspects and examples.

Also, when reference is made in this application to a method having two or more defined steps or operations, the defined steps or operations can be carried out in any order or simultaneously, unless the context excludes those possibilities.

Although specific examples of the invention have been illustrated and described for purposes of illustration, it will be understood that various modifications may be made without departing from the spirit and scope of the invention. Accordingly, the invention should not be limited except as by the appended claims.

1. A test and measurement instrument, comprising:
one or more ports to connect to hardware under test (HUT);
a set of sensors connected to the HUT and to the instrument;
a display to display one or more signal representations from at least one of the HUT and one or more sensors from the set of sensors; and
one or more processors configured to execute code to cause the one or more processors to:
acquire data from the set of sensors;
form one or more data sets from the data acquired from the set of sensors;
apply one or more machine learning models to the one or more data sets; and
receive a predictive analysis from the one or more machine learning model about the HUT.

2. The test and measurement instrument as claimed in claim 1, wherein the set of sensors connected to the instrument connect to the instrument through a sensor data collector comprised of one of a microcontroller or a data logger.

3. The test and measurement instrument as claimed in claim 1, wherein the code that causes the one or more processors to acquire data comprises code that causes the one or more processors to acquire data from one of either the sensors or from a remote store.

4. The test and measurement instrument as claimed in claim 1, wherein the code that causes the one or more processors to form one or more data sets comprises code that causes the one or more processors to normalize the data, and form one or more training data sets, one or more testing data sets, and one or more prediction data sets.

5. The test and measurement instrument as claimed in claim 1, wherein the code that causes the one or more processors to apply one or more machine learning models to the one or more data sets comprises code that causes the one or more processors to:
receive, through a user interface, an input identifying a selected model to apply to the one or more data sets; and
apply the selected model to the one or more data sets.

6. The test and measurement instrument as claimed in claim 5, wherein the input identifying a selected model comprises an automatic selection, and the code that causes the one or more processors to apply machine learning comprises code that causes the one or more processors to apply a machine learning model with a lowest error rate.

7. The test and measurement instrument as claimed in claim 1, wherein the one or more processors are further configured to execute code that causes the one or more processors to train one or more of the machine learning models dynamically at runtime using data streamed from the sensors.

8. The test and measurement instrument as claimed in claim 1, wherein the code that causes the one or more processors to apply machine learning to the data sets comprises code that causes the one or more processors to:
apply the one or more machine learning models to one or more training data sets to train the one or more machine learning models;
use one or more testing data sets to test the one or more machine learning models; and
adjust parameters for the multiple models to increase accuracy of the multiple models.

9. The test and measurement instrument as claimed in claim 8, wherein the code that causes the one or more processors to apply the one or more machine learning models to one or more data sets to train the one or more machine learning models comprises code that causes the one or more processors to perform feature extraction on the one or more data sets of sensor data.

10. The test and measurement system as claimed in claim 1, wherein the one or more processors are further configured to execute code to cause the one or more processors to produce plots indicating outcomes from the one or more machine learning models.

11. A method, comprising receiving data from a set of sensors connected to hardware under test (HUT);
forming one or more data sets from the data acquired from the set of sensors;
applying one or more machine learning models to the one or more data sets; and
receiving one or more predictions from the one or more machine learning model about likelihood of failure of the HUT.

12. The method as claimed in claim 11, wherein receiving data comprises receiving the data from one of either the sensors or from a remote store.

13. The method as claimed in claim 11, wherein forming one or more data sets comprises normalizing the data, and forming one or more training data sets, one or more testing data sets, and one or more prediction data sets.

14. The method as claimed in claim 11, applying one or more machine learning models to the one or more data sets comprises:
receiving, through a user interface, an input identifying a selected model to apply to the one or more data sets; and
applying the selected model to the one or more data sets.

15. The method as claimed in claim 11, wherein the input identifying a selected model comprises an automatic selection, and applying the machine learning model comprises applying the machine learning model with a lowest error rate.

16. The method as claimed in claim 11, further comprising training one or more of the machine learning models dynamically at runtime using data streamed from the sensors.

17. The method as claimed in claim 11, wherein applying the machine learning to the data sets comprises:
applying the one or more machine learning models to one or more training data sets to train the one or more machine learning models;
using one or more testing data sets to test the one or more machine learning models; and
adjusting parameters for the multiple models to increase accuracy of the multiple models.

18. The method as claimed in claim 17, wherein applying the one or more machine learning models to one or more data sets to train the one or more machine learning models comprises performing feature extraction on the one or more data sets of sensor data.

19. The method as claimed in claim 11, receiving one or more predictions from the one or more machine learning models comprises converting the predictions from the one or more machine learning models to a format that can be displayed on the display.

20. The method as claimed in claim 11, further comprising producing plots indicating outcomes from the one or more machine learning models.
